(19) United States
(12) Patent Application Publication
(10) Pub. No.: US 2026/0244111 A1
(43) Pub. Date: Aug. 20, 2026

(54) METHOD OF PREDICTING PERFORMANCE OF A LITHOGRAPHIC APPARATUS, CALIBRATION OF LITHOGRAPHIC APPARATUS, DEVICE MANUFACTURING METHOD

(71) Applicant: ASML Netherlands B.V., Veldhoven (NL)

(72) Inventors: Hasret ERCISLI, Eindhoven (NL); Alina-Ionela DOBAN, Nuenen (NL)

(73) Assignee: ASML Netherlands B.V., Veldhoven (NL)

(21) Appl. No.: 19/164,455

(22) PCT Filed: Mar. 5, 2024
(86) PCT No.: PCT/EP2024/055740

§ 371 Date: Sep. 11, 2025

(30) Foreign Application Priority Data
Apr. 4, 2023 (EP) 23166628.0

(51) Int. Cl. G03F 7/00

(52) U.S. Cl. CPC G03F 7/705; G03F 7/70508; G03F 7/70516; G03F 7/70525; G03F 7/70633

(57) ABSTRACT

Disclosed is a method of predicting performance of a lithographic apparatus. The method comprises: providing calibration data relating to a plurality of fields that have been exposed by the lithographic apparatus on one or more substrates, wherein a field exposure time or a related parameter is varied for at least two said fields of said plurality of fields; generating a performance model based on the calibration data; and using the performance model to determine a set of parameter of interest data for a first plurality of product fields based at least upon field exposure time data describing field exposure times or a related parameter for said plurality of product fields.

### CROSS-REFERENCE TO RELATED APPLICATIONS

This application claims priority of EP application 23166628.0 which was filed on Apr. 4, 2023 and which is incorporated herein in its entirety by reference.

### FIELD

The invention relates to lithographic apparatuses, and in particular to predicting the performance of lithographic apparatuses for calibration or other purposes. The invention further relates to processing apparatuses and computer program products for implementing such methods. The invention further relates to methods of device manufacture.

### BACKGROUND

A lithographic process is one that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a field (e.g. comprising part of, one, or several product dies) on a substrate (e.g. a silicon wafer). Transfer of the pattern is typically via imaging onto a layer of radiation-sensitive material (resist) provided on the substrate. Stepping and/or scanning movements can be involved, to repeat the pattern at successive target portions across the substrate. It is also possible to transfer the pattern from the patterning device to the substrate by imprinting the pattern onto the substrate. In the following description of examples, the term “exposure” may be used for convenience to refer to the step of applying a pattern to a field or to a substrate, without indicating any limitation to optical imaging or to exclude imprinting.

A key performance parameter of the lithographic apparatus is the overlay error. This error, often referred to simply as “overlay”, is the error in placing a product features in the correct position relative to features formed in previous layers. As device structures become every smaller, overlay specifications become ever tighter. Overlay will be used as a main example of performance parameter in the present disclosure, while the concepts and techniques disclosed herein can in principle be applied to the measurement and improvement of other performance parameters as well. Examples of performance parameters of a lithographic process include for example critical dimension (CD), CD uniformity and the like.

Currently the overlay error is controlled and corrected by means of methods such as advanced process control (APC) described for example in US2012008127A1 and wafer alignment models described for example in US2013230797A1.

Within the lithographic apparatus, wafer alignment models are conventionally applied based on measurement of alignment marks provided on the substrate. The measurements are made by the lithographic apparatus as a preliminary step of every patterning operation. The alignment models may include higher order models, to correct for non-linear distortions of the wafer. The alignment models may also be expanded to take into account other measurements and/or calculated effects such as thermal deformation during a patterning operation

To achieve good performance in the lithographic apparatus, it is generally necessary to perform a calibration of the apparatus after any interruption in operation. Calibration, broadly speaking, involves (i) using the apparatus, (ii) measuring the performance of the apparatus and (iii) based on errors observed in the measured performance, controlling the apparatus to correct the errors and improve performance in subsequent production. To achieve the highest possible performance, many individual variables have to be measured and taken into account.

As an example of such variables, some errors may be classed as “intra-field” errors that recur systematically depending on the position within each field. Other errors may be classed as “inter-field” errors that recur systematically as a function of position on the substrate as a whole. Furthermore, overlay in a particular field may be dependent on the particular scanning direction and/or stepping direction that is used by the lithographic apparatus to expose all the fields in an efficient manner. Changes in the product field size and/or exposure sequence and exposure settings (such as velocity, acceleration, jerk during the exposure(s), and in between exposure(s)) may therefore change the performance of the apparatus.

Consequently, to obtain highest performance currently requires new calibration of the lithography apparatus for each change in the product pattern (field size), or even if a new exposure sequence or new grid positioning is to be used. Calibration may have to be performed separately for each chuck (substrate support or wafer table) that may be used within the apparatus. Production is interrupted during the calibration. This directly reduces the production throughput of the lithographic apparatus. If the apparatus will be used for a long period to produce the same product, the lost throughput may be acceptable. Often, however, a lithographic apparatus is used to produce a number of different product layouts day-by-day or hour-by-hour, according to customer demand. Calibrating the apparatus for each individual layout or pattern is unfeasible, even for relatively modest numbers of individual layouts, since it would significantly reduce production throughput. On the other hand, not calibrating for each new design may significantly limit the overlay performance that can be achieved.

Another example of a variable which is of particular relevance to this disclosure, is the time taken to expose each field. This field exposure time may vary due to differences in field sizes or in exposure speed (scan speed) or exposure acceleration profile during an exposure. In particular, it is known to optimize the scan speed per field (or for certain subsets of fields) on a substrate, depending for example on the field location on the substrate and/or the complexity of the patterns being exposed for each field. It can be shown that certain parameters of interest, for example overlay, show a dependency on this field exposure time.

### SUMMARY OF THE INVENTION

In a first aspect of the invention, there is provided a method of predicting performance of a lithographic apparatus, the method comprising: providing calibration data relating to a plurality of fields that have been exposed by the lithographic apparatus on one or more substrates, wherein a field exposure time, time between exposures or a related parameter is varied for at least two said fields of said plurality of fields; generating a performance model based on the calibration data; and using the performance model to determine a set of parameter of interest data for a first plurality of product fields based at least upon field exposure time data describing field exposure times or a related parameter for said plurality of product fields.

Further aspects, features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example, with reference to the accompanying drawings in which:

FIG. 1 depicts a lithographic apparatus together with other apparatuses forming a production facility for semiconductor devices;

FIG. 2 depicts the principle of a calibration method according to an embodiment of the invention;

FIG. 3(a) depicts a high level figure of a performance model according to prior art;

FIG. 3(b) depicts a high level figure of a performance model according to an embodiment;

FIG. 4 shows schematically an example of a calibration pattern usable in the method of FIG. 2;

FIG. 5 is a flowchart of a calibration method according to an embodiment of the invention, including the manufacture of devices using the calibration method;

FIG. 6 is a schematic diagram of a calibration substrate patterned by a lithographic apparatus with a first exposure sequence in the method of FIG. 5;

FIG. 7 illustrates the application of calibration patterns on a calibration substrate with four different exposure sequences in the method of FIG. 5;

FIG. 8 illustrates the structure of a performance model in one embodiment of the method of FIG. 5; and

FIG. 9 illustrates the calculation of certain example components in the performance model, including a dynamic intra-field component indexed by a field exposure time value.

### DETAILED DESCRIPTION

Before describing embodiments of the invention in detail, it is instructive to present an example environment in which embodiments of the present invention may be implemented.

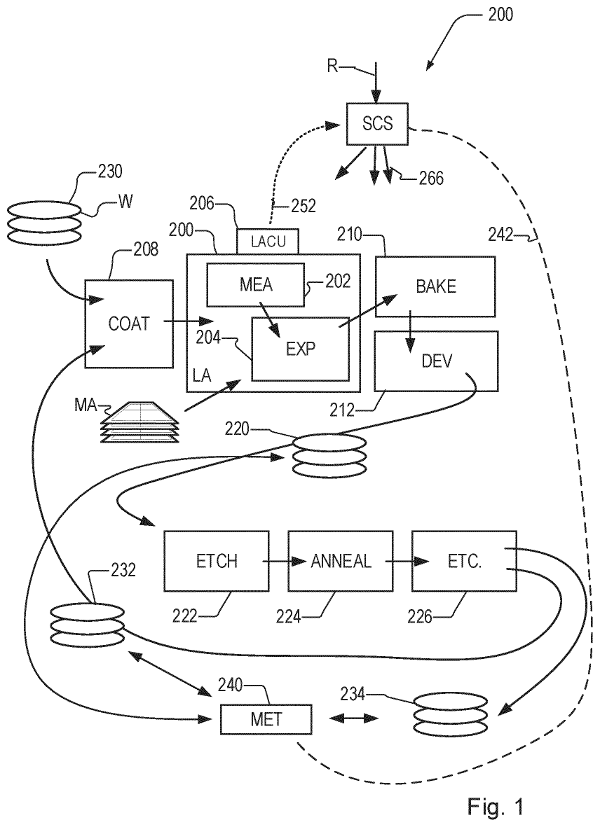

FIG. 1 at 200 shows a lithographic apparatus LA as part of an industrial production facility implementing a high-volume, lithographic manufacturing process. In the present example, the manufacturing process is adapted for the manufacture of for semiconductor products (integrated circuits) on substrates such as semiconductor wafers. The skilled person will appreciate that a wide variety of products can be manufactured by processing different types of substrates in variants of this process. The production of semiconductor products is used purely as an example which has great commercial significance today.

Within the lithographic apparatus (or “litho tool” 200 for short), a measurement station MEA is shown at 202 and an exposure station EXP is shown at 204. A control unit LACU is shown at 206. In this example, each substrate visits the measurement station and the exposure station to have a pattern applied. In an optical lithographic apparatus, for example, a projection system is used to transfer a product pattern from a patterning device MA onto the substrate using conditioned radiation and a projection system. This is done by forming an image of the pattern in a layer of radiation-sensitive resist material.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. The patterning MA device may be a mask or reticle, which imparts a pattern to a radiation beam transmitted or reflected by the patterning device. Well-known modes of operation include a stepping mode and a scanning mode. As is well known, the projection system may cooperate with support and positioning systems for the substrate and the patterning device in a variety of ways to apply a desired pattern to many target portions across a substrate. Programmable patterning devices may be used instead of reticles having a fixed pattern. The radiation for example may include electromagnetic radiation in the deep ultraviolet (DUV) or extreme ultraviolet (EUV) wavebands. The present disclosure is also applicable to other types of lithographic process, for example imprint lithography and direct writing lithography, for example by electron beam.

The lithographic apparatus control unit LACU which controls all the movements and measurements of various actuators and sensors to receive substrates W and reticles MA and to implement the patterning operations. LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus.

Before the pattern is applied to a substrate at the exposure station EXP, the substrate is processed in at the measurement station MEA so that various preparatory steps may be carried out. The preparatory steps may include mapping the surface height of the substrate using a level sensor and measuring the position of alignment marks on the substrate using an alignment sensor. The alignment marks are arranged nominally in a regular grid pattern. However, due to inaccuracies in creating the marks and also due to deformations of the substrate that occur throughout its processing, the marks deviate from the ideal grid. Consequently, in addition to measuring position and orientation of the substrate, the alignment sensor in practice must measure in detail the positions of many marks across the substrate area, if the apparatus is to print product features at the correct locations with very high accuracy. The apparatus may be of a so-called dual stage type which has two substrate tables, each with a positioning system controlled by the control unit LACU. While one substrate on one substrate table is being exposed at the exposure station EXP, another substrate can be loaded onto the other substrate table at the measurement station MEA so that various preparatory steps may be carried out. The measurement of alignment marks is therefore very time-consuming and the provision of two substrate tables enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations. Lithographic apparatus LA may for example is of a so-called dual stage type which has two substrate tables and two stations-an exposure station and a measurement station-between which the substrate tables can be exchanged.

Within the production facility, apparatus 200 forms part of a “litho cell” or “litho cluster” that contains also a coating apparatus 208 for applying photosensitive resist and other coatings to substrates W for patterning by the apparatus 200. At an output side of apparatus 200, a baking apparatus 210 and developing apparatus 212 are provided for developing the exposed pattern into a physical resist pattern. Between all of these apparatuses, substrate handling systems take care of supporting the substrates and transferring them from one piece of apparatus to the next. These apparatuses, which are often collectively referred to as the track, are under the control of a track control unit which is itself controlled by a supervisory control system SCS, which also controls the lithographic apparatus via lithographic apparatus control unit LACU. Thus, the different apparatus can be operated to maximize throughput and processing efficiency. Supervisory control system SCS receives recipe information R which provides in great detail a definition of the steps to be performed to create each patterned substrate.

Once the pattern has been applied and developed in the litho cell, patterned substrates 220 are transferred to other processing apparatuses such as are illustrated at 222, 224, 226. A wide range of processing steps is implemented by various apparatuses in a typical manufacturing facility. For the sake of example, apparatus 222 in this embodiment is an etching station, and apparatus 224 performs a post-etch annealing step. Further physical and/or chemical processing steps are applied in further apparatuses, 226, etc. Numerous types of operation can be required to make a real device, such as deposition of material, modification of surface material characteristics (oxidation, doping, ion implantation etc.), chemical-mechanical polishing (CMP), and so forth. The apparatus 226 may, in practice, represent a series of different processing steps performed in one or more apparatuses. As another example, apparatus and processing steps may be provided for the implementation of self-aligned multiple patterning, to produce multiple smaller features based on a precursor pattern laid down by the lithographic apparatus.

As is well known, the manufacture of semiconductor devices involves many repetitions of such processing, to build up device structures with appropriate materials and patterns, layer-by-layer on the substrate. Accordingly, substrates 230 arriving at the litho cluster may be newly prepared substrates, or they may be substrates that have been processed previously in this cluster or in another apparatus entirely. Similarly, depending on the required processing, substrates 232 on leaving apparatus 226 may be returned for a subsequent patterning operation in the same litho cluster, they may be destined for patterning operations in a different cluster, or they may be finished products to be sent for dicing and packaging.

Each layer of the product structure requires a different set of process steps, and the apparatuses 226 used at each layer may be completely different in type. Further, even where the processing steps to be applied by the apparatus 226 are nominally the same, in a large facility, there may be several supposedly identical machines working in parallel to perform the step 226 on different substrates. Small differences in set-up or faults between these machines can mean that they influence different substrates in different ways. Even steps that are relatively common to each layer, such as etching (apparatus 222) may be implemented by several etching apparatuses that are nominally identical but working in parallel to maximize throughput. In practice, moreover, different layers require different etch processes, for example chemical etches, plasma etches, according to the details of the material to be etched, and special requirements such as, for example, anisotropic etching.

The previous and/or subsequent processes may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which litho cell LC is located also includes metrology system which receives some or all of the substrates W that have been processed in the litho cell. Metrology results are provided directly or indirectly to the supervisory control system SCS. If errors are detected, adjustments may be made to exposures of subsequent substrates, especially if the metrology can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Also shown in FIG. 1 is a metrology apparatus 240 which is provided for making measurements of parameters of the products at desired stages in the manufacturing process. A common example of a metrology station in a modern lithographic production facility is a scatterometer, for example a dark field scatterometer, an angle-resolved scatterometer or a spectroscopic scatterometer, and it may be applied to measure properties of the developed substrates at 220 prior to etching in the apparatus 222. Using metrology apparatus 240, it may be determined, for example, that important performance parameters such as overlay or critical dimension (CD) do not meet specified accuracy requirements in the developed resist. Prior to the etching step, the opportunity exists to strip the developed resist and reprocess the substrates 220 through the litho cluster. The metrology results 242 from the apparatus 240 can be used to maintain accurate performance of the patterning operations in the litho cluster, by supervisory control system SCS and/or control unit LACU 206 making small adjustments over time, thereby minimizing the risk of products being made out-of-specification, and requiring re-work.

Additionally, metrology apparatus 240 and/or other metrology apparatuses (not shown) can be applied to measure properties of the processed substrates 232, 234, and incoming substrates 230. The metrology apparatus can be used on the processed substrate to determine important parameters such as overlay or CD.

As is well known, the pattern applied in one exposure covers only a small portion of the substrate at a time, and the same pattern is typically applied repeatedly over the substrate to make full use of the capacity of the substrate and of the production facility as a whole. The portion to which the pattern is applied is termed a “field”, and its maximum size is limited by the field of view of the optical projection system and other limitations of the apparatus design. On the other hand, not all products require a die which fits neatly within that maximum field size. Wasted space on a substrate is not tolerable in view of the cost of establishing and running the production facility, and so for each product a particular size and shape smaller than the maximum size will generally be selected. In the example of the scanning mode of operation, the lithographic apparatus may be controlled to operate with a shorter scan length and/or a shorter step size, to ensure optimum filling of the substrate area with fields of and particular size and shape.

As explained in the introduction, to obtain best performance in terms of overlay or other performance parameters, a set of calibration measurements is performed on one or several substrates to which calibration patterns have been applied by the individual lithographic apparatus. In practice, as mentioned in the introduction, some or all of the calibration patterning may be repeated using the different substrate tables or “chucks” WTa, WTb. The calibration patterning operations impact the throughput of product substrates. One particular problem in this regard is that overlay performance of a particular lithographic apparatus may be different for different products, exposure settings (e.g., exposure time/speed, acceleration, jerk during exposure and the dynamical settings such as settling time used in-between exposures, including row transitions) and layouts. For example some layouts have different field sizes. An operator may wish to use the same lithographic tool for several products, each with a different field size. Even if the field size does not change, other parameters of the exposure process may change, for example the sequence of up/down and left/right movements used in the exposure of fields in a grid layout, the field exposure time(s) per field, time between field exposures and/or the position of the grid relative to the substrate. Also, the inventors discovered that the overlay performance is also dependent on other settings outside of the exposure (time between exposures, speed, acceleration and/or jerk of the substrate stage between exposures, row transitions). Therefore to obtain best performance it may be necessary to carry out calibrations specific to each product and each grid layout, and each chuck, before starting production of the product. This significantly increases the time, and therefore the cost, of the calibration process.

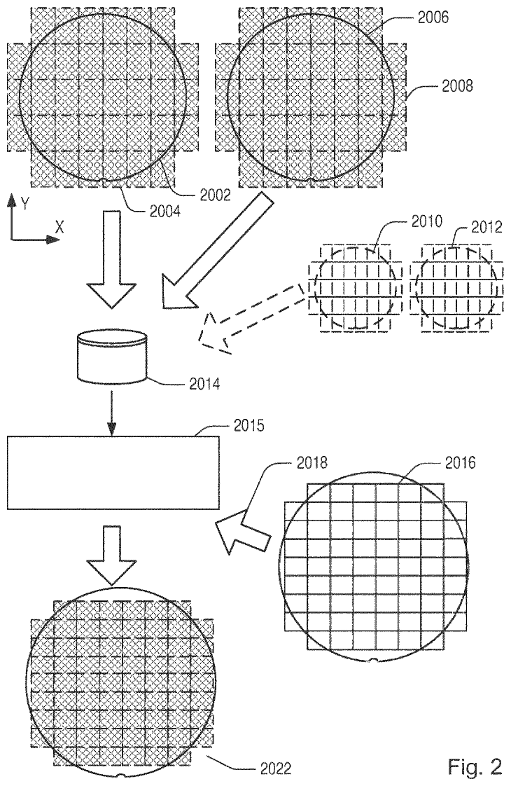

FIG. 2 shows the principle of an exemplary method of calibration according to an embodiment. The concepts disclosed herein improve on the calibration method described within in WO2017080735A1, which is incorporated herein by reference.

A first substrate 2002 may have a calibration pattern applied to a first plurality of fields 2004. In the present example, the substrate is a calibration substrate on which a calibration pattern is applied to a plurality of equally sized and spaced fields. A second substrate 2006 may have a calibration pattern applied to a plurality of fields 2008. Optionally, a third substrate 2010 and a fourth substrate 2012 (and optionally more substrates) may have calibration patterns applied to a plurality of fields. While the present example describes the use of dedicated calibration patterns and dedicated calibration substrates, the terms “calibration pattern” and “calibration substrate” are not intended to exclude the use of actual product patterns for the purposes of calibration.

Each field has, for example, a height in a Y direction and a width in an X direction. (It will be understood that these terms refer only to an arbitrary coordinate system defined by the two perpendicular directions of the substrate plane). In one example of the method, the fields 2004, 2008 on the first and second substrates in this example have the same layout (same size, shape and positions) as shown in FIG. 2. They differ only in the sequence of step and scanning movements that are used to apply the patterns. In other words, fields 2004 on the first substrate are exposed using a first exposure sequence, fields 2008 on the second plurality are exposed using a second exposure sequence different from the first one. Similarly, the third and fourth substrates, where provided, may be provided with calibration patterns having the same field size, field shape and field position as each another. The fields applied to the third and fourth substrates may differ from those of the first and second substrates, however, differing in field positions, and/or different field size or shape.

Substrates 2002, 2006, 2010 and 2012 are shown in FIG. 2 as separate substrates, which may be a convenient implementation. However, methods for obtaining multiple measurements on one substrate may also be used, as will be explained in further detail below. Different field sizes could in principle be mixed on a single substrate, provided that the performance of the apparatus in applying patterns with these different field sizes can be measured separately.

As mentioned above, the maximum size of a field is determined by the design of the lithographic apparatus. In the illustrated example, the fields 2004 and 2008 on the first and second substrates 2002 and 2006 have this maximum field size. Accordingly, particular products will generally be designed and laid out using smaller fields. (In other examples it may be that the lithographic apparatus will be used for the production of products all having smaller field sizes. In such a case, the calibration patterns may be applied with a smaller field size, closer to the maximum field size of the intended product layouts.)

In the method disclosed herein calibration measurements are performed on the patterned substrates 2002, 2006, 2010, 2012 and the resultant calibration data used to obtain corrections for use in controlling the lithographic apparatus when applying product patterns to subsequent substrates. In the present method, however, calibration substrates and measurements (calibration data) are not prepared for every different size and shape of product field. Rather, calibration data representing the performance of the apparatus on fields of applied using different exposure sequences (fields 2004, 2008 in this example) is gathered together in a database 2014 and used to synthesize the information needed to calibrate the apparatus for a product layout and exposure sequence. Exposure sequence may comprise, for example, one or more of the parameters: field exposure time, velocity/acceleration/jerk profile of field exposure(s) and time between field exposure(s) including row-transition. From the database of measurements of calibration substrates with different exposure sequences, a performance model 2015 is derived that may be used to obtain a set of data specific to a product layout and exposure sequence different from the layout and exposure sequence of the physical calibration patterns and measurements. The performance model is used to predict the performance of the lithographic apparatus when applying a product pattern with a particular product layout and exposure sequence, field size and shape.

As an example, a designed product layout for a product substrate comprises a number of fields 2016. In this example, each field has a particular set of field dimensions which is different to the dimensions of the fields 2004, 2008. The designed product layout and exposure sequence are specified with other parameters in a product recipe 2018. The product recipe is used with the performance model 2015 to obtain a specific performance model 2022 that predicts the performance of the lithographic apparatus when patterning a substrate using the product layout and exposure sequence specified in the recipe. The predicted behavior may be used as input for a correction model in a lithographic apparatus. Metrology apparatus 240 of FIG. 1 may be used to make the measurements. The measurement data may be delivered as data 242 to database 2014 that lies within the supervisory control system, or it may lie within the lithographic apparatus control unit LACU. In any case, the control unit LACU in due course receives the information it requires for correcting any performance errors predicted by the specific performance model, and uses the information to improve performance when exposing product fields on real product substrates.

It will be appreciated that the corrections to be applied may be (at least at a simplistic level) an inverse of errors predicted in the specific performance model. Accordingly, it is a matter of implementation whether the performance model 2015 delivers its output firstly in the form of a prediction, which then has to be converted to correction parameters, or whether it is arranged to deliver directly the necessary correction parameters. To a large extent the implementation will depend simply on what form of data is easiest to handle by the control unit and its subsystems. The predicted performance model and/or correction parameters can be combined with corrections from other sources, such as the stability module, substrate process history, predictions on time, speed, acceleration, jerk profiles of the field exposure(s) and in between the field exposure(s), to obtain a complete set of corrections. Of course for the individual substrate, the control unit also uses the alignment model based on measurements taken by alignment sensors and level sensors in the measuring station MEA, immediately prior to exposure.

In order to allow calibration for a number of different variables and a diverse range of error sources, it may be customary to classify each measurement in the database 2014 so that specific subsets of measurement can be used selectively in different contexts. The database 2014 may be indexed so that measurements can be selected based on any number of index variables. Each measurement is effectively positioned at a point in a multi-dimensional space, whose dimensions are the indexing variables. Indexing variables for each performance measurement may comprise, for example, inter-field position (xw, yw), intra-field position (xf, yf) and field center position (xc, yc). Additional indexing variables for sub-sampling the measurement data may comprise for example scanning direction (SU, SD), stepping direction (SL, SR), or any other variable that may be correlated with a physical error source. The index variables in database 2014 can be used (e.g., in any combination, e.g., SUSL instead of only SU) in the performance model 2015 to predict performance when those variables vary in a production situation.

A particular feature of the database 2014 in this prior art example (i.e., as described in the aforementioned WO2017080735A1), is that the performance measurements are also indexed by a time value, represented on a normalized scale, which represents variation of time within the exposure sequence by which the calibration patterns were applied. This normalization of the time value makes it easy to relate time values between exposure sequences having different durations in real time. The basic concept is to use the exposure order of fields of a substrate as a time metric (referred to therein as normalized time) when fitting a dynamic model to the measured calibration data for analysis of a dynamic component of the calibration data. The calibration data for each exposed calibration substrate is represented on a scale from 0 to 1, where 0 represents the beginning of exposing the first field of each calibration substrate and 1 represents the end of exposing the final field, the intermediate fields being represented on that scale in exposure order. The data can then be plotted (e.g., per other index values such as scan/step direction) as field (spatial) coordinate versus this normalized time and a model fitted to this representation.

However, there are disadvantages to using the field expose order as normalized time to calibrate inter-field overlay differences. In some cases, the exposure time and/or exposure speed may vary when exposing different layouts, for example when shorter fields are exposed or for certain edge fields from same image. Exposure speed optimization is sometimes performed to optimize exposure speed for certain fields or subsets of fields on a substrate. Overlay fingerprint of a field changes as the field expose scan speed changes. Presently, the same layouts exposed with different scan speeds are being corrected with the same grid corrections. This is not optimal, and as such this speed dependent inter-field overlay effect is not calibrated by scanner.

Therefore it is proposed to use field exposure time (or a related parameter such as field exposure speed), i.e., the time taken per exposure of each field, as a parameter to calibrate a parameter of interest correction for each field. Similarly, the time spent in between field exposures can be also used as an calibration parameter, as well as velocity, acceleration and jerk profiles during exposure and in between field exposures. The method may comprise calibrating and using a performance model for predicting the performance of a lithographic apparatus when applying a product pattern with a particular product layout and exposure sequence, field size and shape, using the exposure time per field as an input.

As such, referring again to FIG. 2, it can be further appreciated that one or more of the patterned substrates 2002, 2006, 2010, 2012 are exposed with variation in field exposure time (duration of the exposure of each field) or a related parameter such as field exposure speed, such that the resultant calibration data relates to field exposure time variation. Furthermore, product recipe 2018 will also describe the field exposure time layout describing the field exposure time per-field across the substrate.

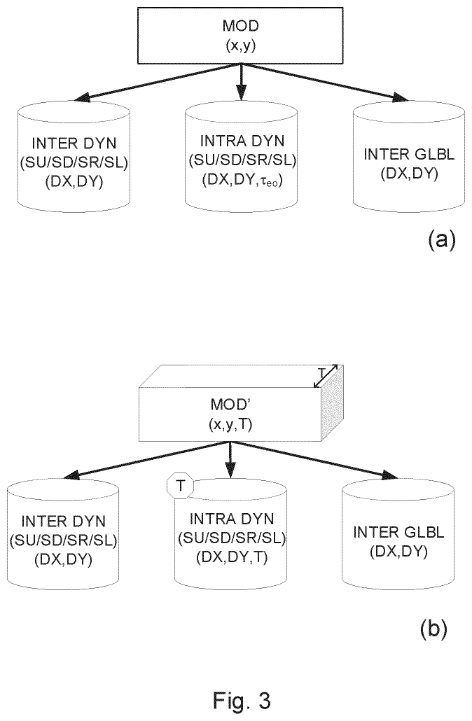

FIG. 3(a) illustrates schematically a high-level calibration logic of the performance model MOD described in WO2017080735A1. At a basic level, the model MOD calibrates three fingerprint components: inter-field dynamic INTER DYN, intra-field dynamic INTRA DYN and inter-field global INTER GLBL. Each of the dynamic components are described in terms of x-displacement DX and y-displacement DY per scan/step direction. The intra-field dynamic fingerprints INTRA DYN are additionally dependent on the normalized time Teo (based on exposure order). FIG. 3(b) is an equivalent drawing of a performance model MOD′ according to an embodiment. The difference in this case is the dependence of the intra-field dynamic component INTRA DYN, and therefore the model itself, on field exposure time T.

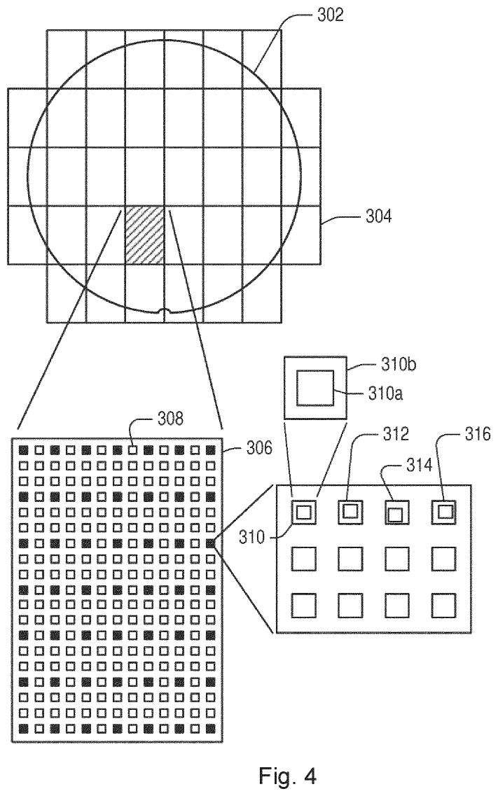

FIG. 4 shows an exemplary calibration substrate 302 as may be used in embodiments disclosed herein. As described above, calibration measurements in accordance with one embodiment of the method may be carried out on a plurality of calibration patterns applied to one or more calibration substrates. The substrate is divided into a number of fields 304, each of which has a calibration pattern 306 applied to it. The pattern may be defined by providing a special calibration patterning device in the lithographic apparatus. Alternatively, a real product design may contain features usable for calibration. In one example, the target pattern comprises overlay targets located in target areas 308 uniformly spaced in a grid pattern across every field. As illustrated in the enlarged insert, each target area 308 may contain a plurality of individual targets 310, 312, 314, 316 etc. These targets are offset from one another by small amounts, while remaining at the general location of the area 308. This provision of multiple targets with offsets is to allow multiple exposures and multiple overlay measurements to be performed on the same substrate and at substantially the same locations. The offsets may be for example measured in tens of microns, while the field size is measured in tens of millimeters.

The design of the targets and the nature of the measurement taken may depend on which parameters of performance are to be improved by the calibration. One parameter of interest, which will be assumed in the following examples, is overlay. Overlay relates to positioning errors in the plane of the substrate (X and Y directions). Another parameter of interest may be focus, which relates to positioning errors normal to the plane of the substrate (Z direction). Targets for measuring these and/or other performance parameters may be provided on the same calibration substrates, or on different calibration substrates.

Referring to the example case of overlay targets, each individual target typically comprises a bottom mark in an underlying layer and a top mark to be formed in the present lithographic apparatus. The bottom marks may have been formed using the same lithographic apparatus or a different one. During application of a calibration pattern, a top mark is applied overlying a particular bottom mark in each target area 308. For example, in a particular calibration patterning operation, top mark 310a may be applied over bottom mark 310b. During a calibration measurement, the overlay error between the top target mark and the bottom target mark is measured. Overlay error causes the marks to be misaligned in one or both of the X and Y directions.

Within each individual target, features may typically be provided to allow measurement in both X and Y directions in a single structure target, or different targets may be provided in a composite target, for measuring overlay in X and Y separately. The drawing shows each target as a simple “box-in-box” target for the sake of illustration only. The targets may indeed be of ‘box-in-box’ type suitable for image-based overlay metrology; according to modern techniques, however, they may be gratings, to be measured by diffraction-based overlay in a well-known manner. Hybrid targets having both image and grating features may be used. The exact type of target, and indeed the manner of measuring, is a matter of implementation. As mentioned, overlay is not the only performance parameter that might be measured, and other types of target and other metrology techniques may be applied, as appropriate to the parameters of interest.

As an example, each specific target in an overlay target area 308 may have been applied separately during successive exposures using different exposure sequences. As will be described further below, it may be desired that the performance model 2015 can take account of inter-field variations and intra-field variations in performance for the given product field size. It may further be desired that the performance model 2015 can take account of subtle variations in performance that are associated with different scanning directions and/or stepping direction. In other words, a calibration is desired that is specific to a particular exposure sequence, as well as a particular field size and shape, in order to obtain best performance.

Accordingly, in an example, it may be that target 310 has been formed during a first patterning operation, forming a first plurality of fields using a first exposure sequence. Similarly, target 312 may have been formed during a second patterning operation, forming a second plurality of fields using the second exposure sequence. Target 314 may have been formed during a third patterning operation, while target 316 has been formed during a fourth patterning operation. In this way, two or more sets of measurement data can be gathered from the one substrate. These sets of measurement data can be used to generate the performance model, as will be described in more detail below. By suitable design, it is possible to apply all the calibration marks in the same resist layer by multiple exposures.

Instead of performing multiple exposures in the same resist, one could make four cycles of coating, exposure and development on the same substrate. These variations should be considered as variants that do not depart from the basic operation of applying a pattern by one or more exposures using the lithographic apparatus. Any of the above patterning operations can be implemented using multiple “mini dose” exposures, rather than a single exposure. Irradiating the resist material with multiple mini doses allows a target pattern to be applied in which random noise effects are suppressed. For example, four doses of one quarter the desired total dose may be used.

Alternatively or additionally, targets in an overlay target area may be applied during successive exposures using different field dimensions. Whether this is possible will depend on the design of the calibration pattern. Using the example where different field sizes are used to obtain measurement data for the database 2014, it will be noticed that the twelve targets in each area 308 conveniently allow for four sets of measurement data to be gathered for each of the three unique filed dimensions (2004, 2008, 2012).

It can be appreciated that any discussion of a patterning operation or a measurement in the present application therefore may be taken to refer potentially to the performance of several identical operations. It may be desirable that each value be measured several times to obtain a statistically reliable measurement and to eliminate as far as possible the effects of random error sources.

While in this example a reference image providing multiple individual target marks with shifts is illustrated, this is not essential. Other embodiments may be envisaged in which multiple marks are printed with shifts relative to a single reference mark, and separate measurement values can be obtained from them. As also illustrated, even with the types of mark illustrated, multiple exposures can be made without shifts, where a pattern is applied at different field positions across the substrate, or different portions of a field are patterned in different exposures.

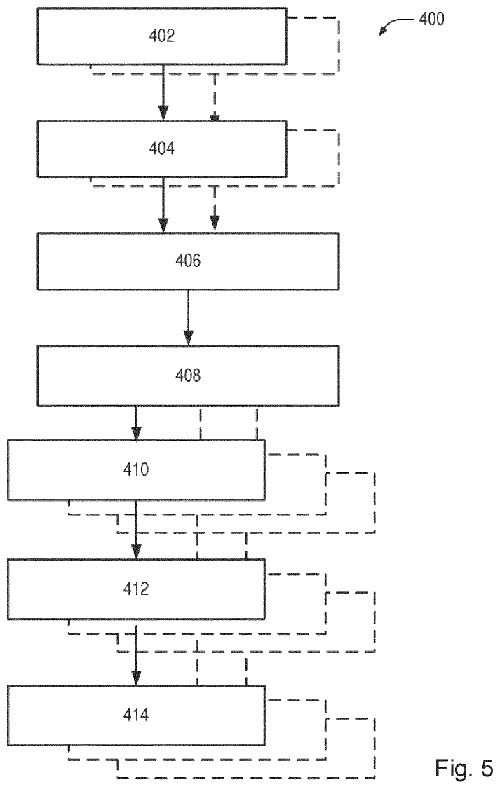

With reference to FIG. 5, a method 400 for carrying out a calibration according to the principles described above will now be described. The reference numerals in this figure refer to the following steps, each of which will be explained in more detail (with reference also to the other drawings):
402: apply calibration patterns to one or more substrates using different field exposure times and exposure sequences;
404: perform calibration measurements on the calibration patterns to obtain calibration data;
406: collect the calibration data into a database where it can be classified into various sets and subsets, based on one or more indexing variables including at least field exposure time or a related parameter (e.g., field exposure speed where the fields are of a common size), and for example further based on scanning and stepping directions;
408: generate a performance model that can be interrogated using the indexing variables including at least the field exposure time or a related parameter;
410: use the performance model to predict performance for product fields having a one or more new layouts (including field exposure time layouts) and/or new exposure sequences, based at least on field exposure time data or related parameter data; and
412: use predicted performance to calculate corrections for the one or more product layouts and exposure sequences;
414: use the calculated corrections in controlling operation of lithographic apparatus to expose product fields according to the product layouts and field exposure times.

As will be seen from the drawing, the steps 402 and 404 can be performed more than once, to create and measure calibration patterns using different field layouts, exposure sequences and/or field exposure time layouts. The steps to obtain the calibration data for each field layout is the same, and so will only be described once.

In step 402 of the method 400, a calibration pattern is applied to a first plurality of fields across a calibration substrate and a second plurality of fields across the same or another calibration substrate. As shown in broken lines, additional calibration patterns may applied, but it is sufficient to consider just two for a simple implementation.

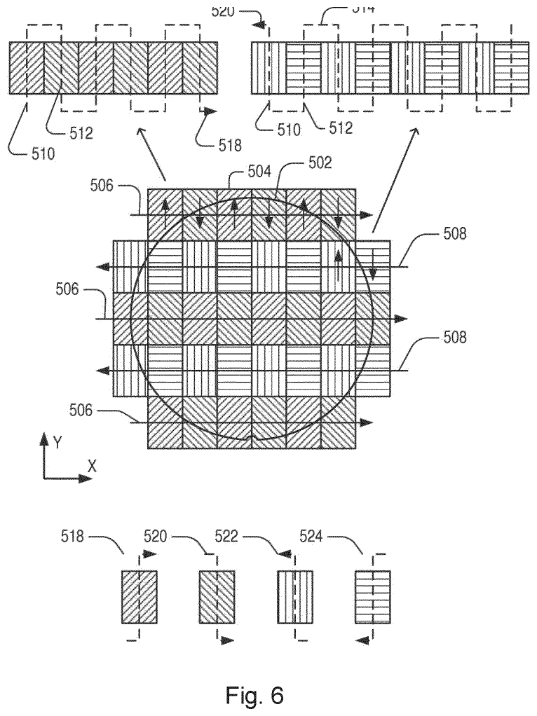

As shown schematically in FIG. 6, a calibration substrate 502 may be divided into a number of fields 504 that are arranged in a grid pattern. During a patterning operation, patterns are applied to each field on the substrate in an exposure sequence. In a scanning-type lithographic apparatus, the exposure sequence comprises a sequence of stepping and scanning movements by which each field on a substrate is patterned in an efficient or advantageous manner. By convention, the stepping direction is aligned with the X axis of the substrate coordinate system. The scanning direction is aligned with the Y axis of the substrate coordinate system (although this is arbitrary). It is to be noted that the stepping and scanning movements to be described are purely relative movements between the patterning device, the optical projection system and the substrate during a patterning operation. These relative movements can be effected in a number of ways. In principle, it does not matter which components move and which remain static, so long as overall their relative movements achieve the desired image formation and image placement. In practical apparatuses, in the scanning mode of operation, movements of the patterning device and the substrate are controlled in a carefully synchronized manner, while the projection system remains largely stationary. On the other hand, for purposes of illustration, the operation can be visualized as if the lithographic apparatus were stepping and scanning over the substrate.

With that in mind, an example exposure sequence for an example field size is indicated by the dashed arrows 518, 520 in the detailed views above the main portion of the figure. Each field is patterned by scanning either in the positive Y direction (referred to for example as the “scan up” SU direction) 510 or in the negative Y direction (the “scan down” SD direction) 512. After exposing a particular field, the apparatus steps in either the negative X direction 514 (referred for example as “stepping left” SL) or in the positive X direction 516 (referred to as “stepping right” SR). After a left or right step, a next field is typically patterned in the opposite direction to that of the previous field. Thus, if a particular field has been exposed by scanning in the “up” direction, the next field is exposed by scanning in the “down” direction. This minimizes unnecessary movement of the lithographic apparatus, thereby reducing the amount of time required to process each substrate. On the other hand, it does mean that each field is exposed using a slightly set of movements. This is the reason that overlay can vary between fields in a systematic manner, depending on the scan and step directions.

It will be understood that the labels “up”, “down”, “left” and “right” are merely convenient labels for explanation and understanding, and to not refer to any particular orientation or reference frame in the physical world. Typically the stepping motion is performed so that the next field is the immediately adjacent field, and exposure progresses row-by-row. This customary “meander” pattern is exploited to some extent in the time-indexed performance models to be described. In principle, alternative sequences can be implemented if they are found to be advantageous.

In this fashion, the calibration pattern is applied successively to each field in a particular row of fields on the calibration substrate, while stepping generally in a left-to-right or a right-to-left direction. When one row of fields has been patterned, the lithographic apparatus applies the calibration pattern to the next row of fields, but (usually) stepping in the opposite direction to the previous row. In the present example, it is considered that the “top” row of fields is exposed first, by stepping in a left-to-right direction (arrow 506), and the next row of fields is exposed in a right-to-left direction (arrow 508).

On the first few fields in FIG. 6, up and down arrows illustrate the scanning direction used when exposing each field. Further, hatching is used to indicate for each field which combination of scan and step directions is used. The insert below the main figure shows how different hatching represents each of the four scan and step combinations used to apply the pattern to different fields on the calibration substrate in the present example. These are: scan up/step right (SUSR) 518; scan down/step right (SDSR) 520; scan up/step left (SUSL) 522; and scan down/step left (SDSL) 524.

As explained above, overlay performance of the lithographic apparatus in a particular field may be partly dependent on the scanning and stepping direction used during the exposure (patterning) of that field. Consequently, as an example overlay performance in a particular field that has been patterned using the up/left combination may differ in a small but systematic way from overlay performance in an identical field that has been patterned using the down/right combination. The calibration method can correct for this systematic error, provided it has suitable sets of measurement data from which to observe the systematic effects. For this reason, in the illustrated method, each field on the calibration substrate is patterned two or more times. In the first embodiment to be described, the patterning operation is repeated with a different exposure sequence so that each field position in the layout has been patterned using the two different scan directions (SU, SD). In a second embodiment, described briefly below, the patterning operation is repeated with different exposure sequences so that each field position in the layout has been patterned using each of the four scan and step combinations discussed with reference to FIG. 6.

Of particular note, the exposure sequences should comprise variation in time taken to expose the fields. Each field will therefore have an associated field exposure time describing the time taken to expose that field. This variation may be implemented for example by varying exposure speed (scan speed) for different fields on each calibration substrate. It is known, in some applications, to use an exposure speed optimization to determine different exposure speeds for different fields of a substrate. Alternatively, or in addition, different field sizes on the substrate may also impose an exposure time variation.

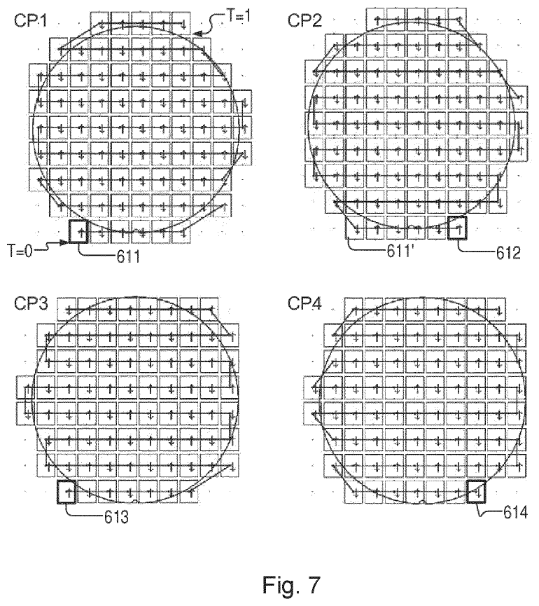

FIG. 7 illustrates how four sets of calibration fields are applied to one or more calibration substrates using different exposure sequences, field exposure times and/or layouts in a real example. Four calibration exposures are labelled CP1, CP2, CP3 and CP4. (These exposures may be performed on different substrates, or they can be made as multiple exposures on the same substrate, using offsets of the type illustrated in FIG. 4 or different exposure speeds.)

Exposure CP1 applies a first plurality of fields and exposure CP2 applies a second plurality of fields. As can be seen, the layout between these two exposures is the same. In the example, each exposure CP1, CP2 comprises 81 fields on a wafer of 300 mm diameter, each field being a full-size field of for example 26 mm by 33 mm. While the layout is the same between exposures CP1 and CP2, each set of fields is applied to its substrate using a different sequence of scan and step movements (different exposure sequence). Exposure CP1 begins with field 611 in a bottom left position, while exposure CP2 begins with field 612 at the bottom right position. Following a different exposure sequence, it will be seen that in each field position of the layout, the exposures CP1 and CP2 use a different scan direction and a different step direction. Thus, for example field 611 in exposure CP2 has a scan up, step right (SUSR) combination, the corresponding field 612 in exposure CP2 as a scan down, step left (SDSL) combination.

Significant calibration benefits can be obtained with only two exposures, using the time-indexed performance model disclosed herein. In other embodiments, further exposures may be performed. If desired, four exposures with the same layout would allow every field position could be exposed with the four possible scan-step combinations SUSR, SDSR, SUSL, SDSL.

For additional benefit, further calibration exposures can be performed using different layouts and/or field exposure speeds. In the illustrated example, third and fourth exposures CP3 and CP4 are made. In the illustrated example, the layout between exposures CP3 and CP4 is the same, but different to the layout in the first and second exposures. The field size is unchanged in this example, but the field positions are shifted half a field in both the X and Y directions. The number of fields in exposures CP3 and CP4 is 77 instead of 81. The beginning fields are labeled 613 and 614. The exposure sequences for the pair of exposures CP3, CP4 are again chosen so that at each field position, the two exposures have different scan directions and different step directions. Thus by combining the fields from exposures CP3 and CP4, full coverage of the substrate by SU fields is obtained, and the same applies to SD, SR, SL. A benefit of obtaining additional measurement data with shifted field positions is that the calibration can isolate local effects on the substrate table by combining measurement data from the four exposures. Local effects can arise for example from the positioning and operation of extraction channels for immersion fluid, or other structures in the substrate table.

Referring also now to step 404 of FIG. 5, measurements are carried out on the calibration substrate(s), such as measuring the overlay error (or other parameter of interest) revealed by the targets 310, 312, 314, 316. Some or all of the calibration measurements can for example be carried out using the metrology apparatus 240. In some examples, some or all of the calibration measurements can alternatively be carried out using the alignment sensor AS or other sensors within the lithographic apparatus LA. All the sets of calibration data are gathered in the database 2014 for classification and subsequent processing.

Referring again to FIG. 5, in step 406 the calibration data (e.g., data measured from the calibration substrates) for the individual fields is classified into sets and subsets based on a desired set of indexing variables of interest. In this particular example, the indexing variables include the field exposure time and scan and step directions used during the patterning operations. For example, all measurement data from fields that have been patterned using the scan up direction can be selected using a scan direction index variable. These index values may be combined, e.g., measurement data from fields that have been patterned using the scan up direction and step left direction can also be selected using a combined scan/step direction variable (e.g., SUSL).

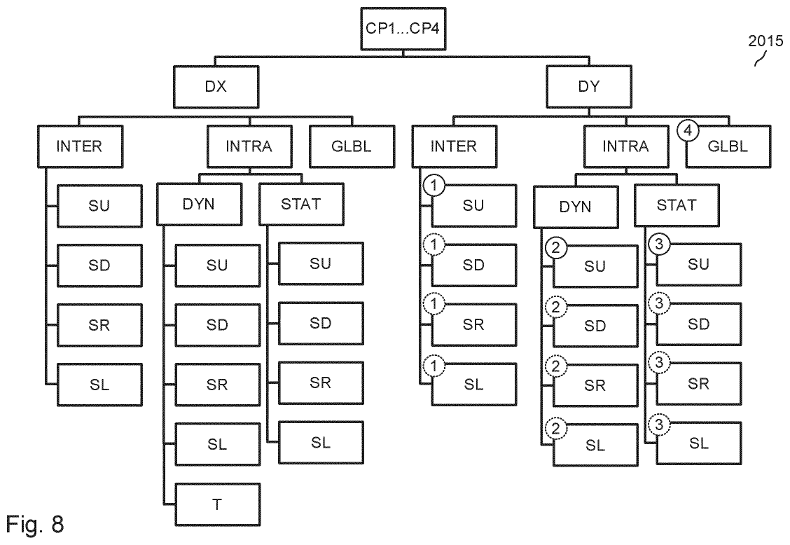

Referring now to FIG. 8 in conjunction with FIG. 5, step 408, FIG. 8 shows the structure of the performance model 2015 in a first embodiment of the present disclosure. Using the indexing variables of the database 2014, different subsets of measurement data from the exposures CP1 to CP4 are accessed and used to calculate various components of a performance model. In the case where the measurement data are overlay error measurements, performance is modeled separately in terms of overlay DX in the X direction and overlay DY in the Y direction. In the present example, processing in both branches DX and DY is identical, but this need not be the case. Referring to the DY model as an example, “intra-field” and “inter-field” error components (“fingerprints”) are extracted from measurement data. As is well-known the errors present in the lithographic process include errors that recur systematically depending on the position (xf, yf) within each field and those errors that recur systematically as a function of position (xw, yw) on the substrate as a whole.

Each component of the performance model 2015 comprises a suitable parameterized model fitted to a certain subset (sub-sampling) of the measurement data. The skilled reader is aware of the range of different models that can be employed. The most common example is a two-dimensional polynomial model. The order of the model (the number of coefficients of the polynomial) is selected to achieve a desired spatial frequency response. For inter-field components, a model based on radial functions may be preferred. The different subsets are accessed using the index variables. In the illustrated performance model for y-direction overlay DY, inter-field components are in the branch DY-INTER. Inter-field components SU, SD are generated by fitting models to the data for the scan up fields and scan down fields, respectively. Similarly, inter-field components SR and SL are generated by fitting models to the data for the step right and step left fields, respectively. It will be appreciated that the same measurement data points will appear in more than one subset of data. For example, each field has both a scan direction and a step direction and so a given measurement point may contribute to (for example) the SU component and the SR component. Each of the components is expressed as a deviation above and below an average, so that components may be added without “double counting” a measurement.

In the intra-field branch DYN-INTRA is similarly arranged. The skilled person is familiar with methods to extract intra-field fingerprints, and a suitable method can be used for the different subsets of the measurement data. In one method, an “average field” is determined by combining measurements from all the fields in the relevant subset. This average field provides, for each intra-field position, estimates of the overlay DY. Many different types of algorithms may be considered for this purpose, and a simple average could in principle be used. Separate average fields are calculated from the subsets of the measurement data selected for each scan direction SU, SD and step direction SL, SR (or any of the combination of the indexing parameters such as SUSL, SUSD, SDSR, SDSL). As in the case of the inter-field components, intra-field fingerprints may be expressed as deviations from an average field, so that they contain only the component of overlay error that is specifically correlated with their particular scan direction.

Note that for one or both the inter-field branch and intra-field branch, the components may differ, e.g., either or both may comprise only scan direction components SU, SD or only step direction components SL, SR (or any of the combination of the indexing parameters such as SUSL, SUSD, SDSR, SDSL). Alternatively, either or both branches may be arranged as illustrated in FIG. 11 of WO2017080735A1. In this example, instead of having components specific to scan up and scan down directions, and components specific to step right and step left directions, the model has subsets specific to the four combinations of movements: scan up/step right (SUSR), scan down/step right (SDSR), scan up-step left (SUSL) and scan down, step left (SDSL). To properly support this model, additional calibration exposures may be needed, so that for each layout the full set of combinations can be exposed at each field position.

In the present example, the intra-field components of the performance model may be divided into dynamic (DYN) components and static (STAT) components. The dynamic component for each scan direction may define an intra-field performance that varies with the field exposure time T. In other words, each of the dynamic components DYN-SU and DYN-SD is a three-dimensional model, representing the way in which the intra-field component of overlay error DY varies with field exposure time T (rather than position in the exposure order/normalized time as per the aforementioned prior art). The static components may be two-dimensional models.

A “global” component GLBL may also be provided in each direction branch of the performance model.

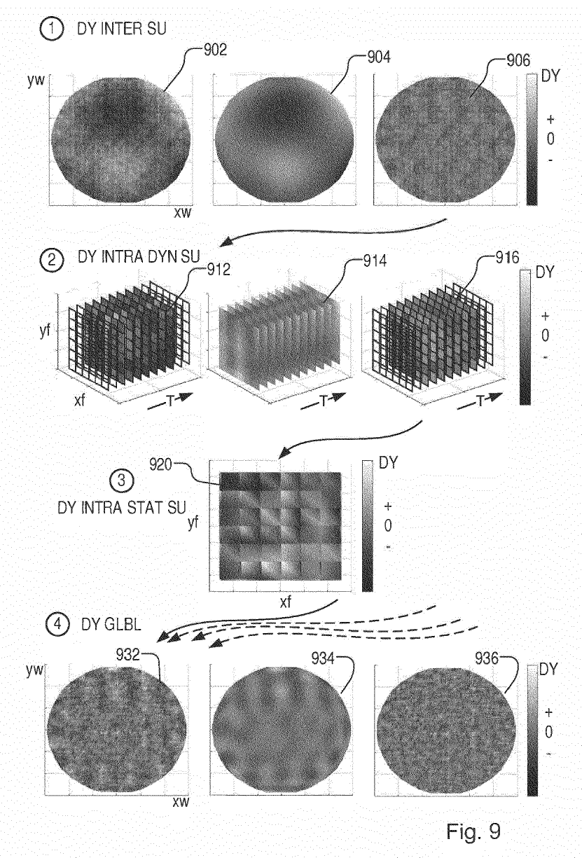

FIG. 9 illustrates the generation of the components of the performance model for the overlay error component DY, with reference to the scan up (SU) components only. The processing for the other components is similar, with only the index variables changing. In the present example, a sequence of calculations is performed that are labeled by circled numbers (1), (2), (3) and (4) in FIG. 9. The same circled numbers are marked on FIG. 8, for ease of reference.

In a first step (1), the inter-field component DY-INTER-SU is calculated. Overlay measurement data 902 is represented by shading on a map of a substrate. The horizontal axis of this map is the position xw in the X direction, and the vertical axis is position yw in the Y direction. A mid-grey shade represents zero overlay error measured at that point on the calibration patterns. The scale represented by shades from black to white is arbitrary, but may be for example on the order of a few nanometers. Note that this data is not from a single exposure, but from a combination of measurements from multiple exposures such as the exposures CP1-CP4. This measurement data has been stored and classified in database 2014 and sub-sampled using the indexing variable scan direction and selecting the value SU. Optionally, certain corrections that will be made by other mechanisms within the lithographic apparatus may have been subtracted, so that the input for the present performance model contains only the uncorrected overlay error.

A parameterized model is fitted to the received data to obtain an inter-field component 904.

This component is also represented on a map of the substrate and is a function of the position (xw, yw). It will be seen that the performance model in this example is a relatively low order polynomial or other suitable model, producing a smoothed representation of the overlay variations observed across the substrate. In the illustrated example, the fit is an 8^{th} order (or lower) polynomial in xw and yw. Having calculated the inter-field component 904 of the performance model, this is subtracted from the measurement data 902 to obtain residual component 906. It can be observed that the residual data has fewer low spatial frequencies, and also has less extreme shading, as would be expected if there is a strong inter-field component in the measured overlay error. This component can be corrected in product exposures, using the performance model to calculate an inter-field correction.

Not shown in FIG. 9, similar calculations are performed to obtain inter-field components of the performance model for the scan down direction (SD component), for the step directions SR, SL (or combinations thereof). Similar calculations are performance of course for the DX component of overlay, but those are quite independent of the DY component, in this implementation.

In the next step (2), the dynamic component DY-INTRA-DYN-SU of the intra-field performance model is calculated, using the residual component 906 as input. This being the intra-field component, measurement data from all the fields having scan up exposure is combined into intra-field measurement data 912 with spatial dimensions corresponding to the dimensions of the largest field size. Intra-field position is indicated by coordinates xf, yf. This being a dynamic component, the data is not only indexed by intra-field position, but also indexed by the field exposure time value T as a third dimension. The data 912 is presented as a series of slices. In the real example, the number of slices is greater than can be shown in the drawing. The number of slices corresponds to the variation of different exposure time(s) in the calibration exposures CP1-CP4, and the data from each field is placed at the field exposure time value. For example, one or more fields exposed at a non-standard exposure time (T1′) due to scan speed may be placed at an interpolated exposure time of T1′; i.e., in between times T1 and T2.

Referring back to FIG. 4, the illustrated example assumes that each field is sampled by a 7×7 grid of measurements. Some grid positions will be empty as shown, where a field overlaps the edge of the substrate. This sampling is represented by the black filled target areas among the target areas 308 in FIG. 4. Of course a higher or lower density of spatial sampling can be chosen if desired. The skilled reader will appreciate that a balance needs to be made so that the number of samples is sufficient for the desired accuracy of the model, but not so great that the calibration time becomes unacceptable. The sampling points need not be on a regular grid, and need not be the same in all fields. Note that the range of DY values represented by the shading in this illustration is smaller than in the data 902-906.

Based on the field exposure time-indexed intra-field data 912, a dynamic intra-field component 914 of the performance model is calculated (DY-INTRA-DYN-SU). This may comprise another parameterized model fitted in three dimensions. In the spatial dimensions, a low order polynomial (e.g. 4^{th} or 6^{th} order inclusive in xf and yf) may be used. In the time dimension, a parameterized model can be used, or the model may simply comprise a number of slices interpolated from the data 912 (in other words a first order fit).

As mentioned above, there may be situations in which the field size exposed for calibration is smaller than the maximum field size. In particular, if the lithographic apparatus is used only to manufacture products with smaller field sizes, a more accurate performance model may be obtained using calibration exposures with layouts and field sizes closer to the product field sizes. In that case, the spatial range of data 912 will be restricted. If it is desired to maintain a given number of samples per slice (e.g. to maintain a 7×7 grid) the spatial sampling density in the central part of the field may be increased. Extrapolation outside the grid of measured sample points may introduce errors and is not recommended.

Having calculated the dynamic intra-field component 914 of the performance model, this may be subtracted from the intra-field measurement data 912 to obtain residual intra-field data 916. It can be observed that the residual data has less extreme shading, as would be expected if there is a strong intra-field component in the measured overlay error. The dynamic intra-field component 914 can be corrected in product exposures, using the performance model to calculate an inter-field correction based on intra-field position and time.

In the third step (3), a static intra-field component 920 (DY-INTRA-STAT-SU) may be calculated from the residual intra-field data 916. The time value is ignored in this static component, so that the 3-dimensional residual data 916 collapses into the two dimensional space. Rather than fitting any model to the data, in this component the raw measurement data may be stored, indexed by intra-field position. Interpolation can be performed when required, for example using a scattered interpolant fit with linear interpolation, or using a 2-dimensional polynomial fit. The shading in the squares of this grid is an artifact of the data visualization. Data points in this example exist only around the corners of the squares. Although a rough 7×7 array of sample points can be observed, intra-field positions are stored with enough precision that the small offsets shown in FIG. 4 are fully represented. Note that the range of DY values represented by the shading in this illustration is much smaller than in the earlier plots. The residual data 916 has much lower amplitude than the earlier components.

Not shown in FIG. 9, similar calculations may be performed to obtain dynamic and static intra-field components of the performance model for the scan down direction (SD component). In the present example, intra-field components are not calculated for the different step directions SR, SL, but in another implementation they could be.

In the fourth step (4), residual data 932 extending over the whole substrate may be calculated as an input to obtain the “global” component DY-GLBL of the performance model 800. The residual data may be calculated by subtracting all of the inter-field and intra-field components from the original measurement data 902, not only the SU component. In this way, residual data 932 represents a component of overlay that is not going to be corrected by any correction calculated from those other components of the performance model. Again the range of DY values represented by the black-white shading is smaller than in the earlier plots, so that the residual overlay is of very low amplitude. However, it may contain components that are systematic and related to peculiarities of the individual lithographic apparatus. To model this residual overlay, a further two-dimensional parameterized model 934 may be defined, using a relatively high order fitting function. The parameterized model may for example be a 16^{th} order (or higher), 17^{th} order (or higher) or 18^{th} order (or higher) polynomial in two dimensions, to allow higher spatial frequencies to be represented than can be represented in the inter-field component 904.

Having obtained the final component 934 of the DY-SU model, a further residual component 936 can be calculated by subtracting component 934 from the data 932. This residual component 936 may be expected to exhibit a low level, high-frequency character. However, there may also be systematic components that can be identified by further analysis, and corrected. For example the plot 936 reveals some circular patterns that may be corrected by a suitable model component. The residual plot may also provide information about root causes of errors, allowing maintenances and/or design improvements.

Having calculated all the components of the performance model 2015, reference is again made to the flow of FIG. 5. At step 410, the various inter-field and intra-field components of the performance model 2015 may be used to predict performance for a real product substrate having a specific layout 2016 and based on a specific arrangement or layout of field exposure times (i.e., field exposure times per field; this may be predicted). The performance model 2015 can be described as a “generic” or “master” performance model, from which specific performance models can be derived for a variety of specific product layouts, exposure speed sequences, field exposure time(s) (e.g., taking into account one or more of speed, acceleration, jerk, time between field exposures including settling time). It may be useful that performance can be predicted for alternative exposure sequences as an “experiment”, without running any specific calibration substrates of the actual field size. More importantly, however, in step 412, corrections based on some or all of the performance model components may be calculated. These corrections may be synthesized from the different components of the performance model, selected by reference to the indexing variables, such as the specific scan and step direction used in each field of the product exposure sequence. Furthermore, for dynamic components, the specific correction is selected also by reference to the field exposure time (or related parameter).

In some cases, it may be desired for the dynamic components to be scaled in accordance with one or more parameters of a product exposure recipe. For example, some dynamic effects may scale according to one or more variables. Examples of such variables include field size, number of exposed fields in a row, scan speed, field exposure time, time between exposures, exposure dose settings. These scale factors and variables may be determined empirically by fitting to appropriate sets of calibration data. These scale factors may alternatively be determined or adjusted by feedback, once production is under way. (Measurements on production substrates can be used to monitor the specific components identified by the performance model, and to correct drift by feedback.)

In step 414 some or all of the components of the performance model 800 are used to calculate one or more sets of correction parameters for use in controlling the lithographic apparatus to apply product patterns to product substrates. For each field on the product substrate, scan direction, step direction, inter-field position and intra-field position are used to select appropriate components of the performance model. Unlike conventional methods, the time value (which varies during the product exposure sequence such as scanning time, stepping time) that during the product exposure sequence is used as an additional indexing variable, so that time-varying effects can be corrected more accurately.

In addition to field exposure time, scan direction and step direction are just two possible indexing variables. The measurement data can be indexed and sub-sampled according to any desired combination of parameters. For example, peripheral regions of the substrate may be classified separately to allow an edge-related component to be added to the performance model, and edge-related errors can be predicted and/or corrected.

As indicated by broken lines in FIG. 5, steps 410, 412, 414 can be repeated for different product layouts, different product exposure sequences and/or different field exposure time layouts, without repeating the costly calibration exposures and measurements of steps 402 and 404. Moreover, it is found that a significant improvement in overlay performance can be obtained with relatively little calibration overhead. Depending on the types of error sources to be corrected, only two calibration exposures CP1 and CP2 may be sufficient. For some localized effects on the substrate scale, adding another pair of calibration exposures CP3, CP4 may be beneficial. However, these few calibration exposures can be used to generate specific corrections for a wide range of layouts and exposure sequences, thereafter.

In the above examples, calibration exposure layouts and exposure sequences have been designed in pairs, or in fours, in which each exposure complements the other(s) to provide full coverage of the substrate area by each subset of scan and step directions. Calibration exposures do not need to be arranged in such complementary pairs or groups, to achieve the same overall effect, however, and any suitable arrangement of calibration layouts and exposure sequences can be used. Incomplete coverage of the substrate area by some components may be tolerable, for example to gain some other benefit.

In all embodiments, both for calibration and in using the model, the field exposure time may be predicted, e.g., based on field size and a proposed field exposure scan speed (or deviation of a field exposure scan speed from a nominal exposure scan speed), acceleration and/or jerk profile.

The terms “radiation” and “beam” used in relation to the metrology devices described herein encompass all types of electromagnetic radiation, in any wavelength range, including infrared wavelengths such as 1000-3000 nm wavelengths.

While the above description describes corrections for a lithographic apparatus/scanner, the determined corrections may also be used for any process and by any integrated circuit (IC) manufacturing apparatus in an IC manufacturing process, e.g., an etch apparatus, which has an effect on the position and/or a dimension of the structures formed within a layer.

The terms “radiation” and “beam” used in relation to the lithographic apparatus encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1.-29. (canceled)

30. A method of calibrating a lithographic apparatus, the method comprising:
providing calibration data relating to a plurality of fields that have been exposed by the lithographic apparatus on one or more substrates, wherein a field exposure time, time between exposures or a related parameter is varied for at least two fields of the plurality of fields;
generating a performance model based on the calibration data; and
using the performance model to determine a set of parameter of interest data for a first plurality of product fields based at least upon field exposure time data describing field exposure times or a related parameter for the first plurality of product fields; and
based on the set of parameter of interest data, supplying corrections to be used by the lithographic apparatus when applying product fields on a product substrate using at least a product field exposure time layout.

31. The method of claim 30, wherein:
for generating the performance model the calibration data is indexed at least partly by the field exposure time or related parameter of the plurality of fields.

32. The method of claim 30, wherein the field exposure time data is predicted based on a proposed exposure scan speed per field of the plurality of fields.

33. The method of claim 32, wherein the field exposure time data is predicted based on an exposure acceleration per field of the plurality of fields.

34. The method of claim 32, wherein the field exposure time data is predicted based on an exposure jerk value per field of the plurality of fields.

35. The method of claim 30, wherein the time between exposures is predicted based on a speed profile of a substrate stage carrying the substrate when moving between two of the plurality of fields.

36. The method of claim 35, wherein the time between exposures is predicted based on an acceleration profile of the substrate stage when moving between two of the plurality of fields.

37. The method of claim 35, wherein the time between exposures is predicted based on a jerk profile of the substrate stage when moving between two of the plurality of fields.

38. The method of claim 30, wherein the calibration data is further indexed on the basis of a scan direction that varies between fields of the plurality of fields within different exposure sequences, and wherein the set of parameter of interest data for the first plurality of product fields is generated at least partly by reference to a scan direction that varies within a production exposure sequence relating to the first plurality of product fields.

39. The method of claim 30, wherein the calibration data is further indexed on the basis of a step direction that varies between fields of the plurality of fields within different exposure sequences, and wherein the set of parameter of interest data for the first plurality of product fields is generated at least partly by reference to a stepping direction that varies within a production exposure sequence relating to the first plurality of product fields.

40. The method of claim 30, further comprising supplying corrections to be used by the lithographic apparatus when applying product fields on the product substrate using a product field layout and a product exposure sequence.

41. A method of controlling a lithographic apparatus comprising:
receiving corrections that have been generated by the method of claim 30;
causing the lithographic apparatus to apply one or more product patterns using the received corrections.

42. A method of manufacturing a device comprising:
controlling a lithographic apparatus to apply one or more product patterns by the method of claim 41; and
forming functional device structures on the substrate in accordance with the applied product pattern.

43. A processing apparatus that predicts performance of a lithographic process, the apparatus comprising a processor arranged to perform the steps of a method of claim 30.

44. An apparatus for calibrating a lithographic apparatus, the apparatus comprising:
storage comprising a performance model generated by the generating step of the method of claim 30;
at least one processor arranged to:
use the performance model to determine a set of data for at least a first plurality of product fields having at least a product field exposure time layout; and
use the set of data to generate corrections to be used while applying a product pattern to plurality of product fields on a product substrate using the product field exposure time layout.

45. A non-transitory computer program product comprising machine readable instructions which, when run on a suitable processor, cause the processor to perform the generating and using steps of the method of claim 30.
